(19) United States
(12) Patent Application Publication
(10) Pub. No.: US 2023/0259670 A1
(43) Pub. Date: Aug. 17, 2023

(54) PERMEABILITY MODELING IN A RESERVOIR SIMULATION MODEL USING DYNAMIC PRESSURE TRANSIENT ANALYSIS

(71) Applicant: Saudi Arabian Oil Comoany, Dhahran (SA)

(72) Inventors: Jubril Oluwa, Dhahran (SA); Ali Essa Al-Mahfoudh, Qatif (SA); Amena Ali Alelg, Qatif (SA)

(73) Assignee: Saudi Arabian Oil Comoany, Dhahran (SA)

(21) Appl. No.: 17/651,339

(22) Filed: Feb. 16, 2022

(51) Int. Cl. G06F 30/20; E21B 41/00

(52) U.S. Cl. CPC G06F 30/20; E21B 41/00; E21B 2200/20

(57) ABSTRACT

A method includes obtaining a log of the reservoir, determining, by a computer processor, a log porosity-thickness for each segment of the log of the reservoir, determining a test permeability-thickness relating to each segment of the log of the reservoir using a dynamic pressure transient analysis, determining a relationship between the test permeability-thickness and the log porosity-thickness, determining a model flow capacity and a model storage capacity for the model, determining a calculated flow capacity using the model storage capacity and the relationship, determining a ratio of the calculated flow capacity to the model flow capacity, correcting the model by applying the ratio to each cell, and planning and executing a reservoir production plan based on the model.

### BACKGROUND

In the oil and gas industry, hydrocarbon fluids are located in porous reservoirs far beneath the Earth's surface. Using data gathered from seismic tools and exploratory wells, a reservoir simulation model of the reservoir may be created. The model numerically represents the reservoir and simulates properties of the reservoir, including fluid flow properties, on a computer. The model may be used to determine the volume of recoverable hydrocarbons in the reservoir and how to best obtain said hydrocarbons. This may be achieved by simulating porosity and permeability throughout the reservoir. As such, it is important that the model accurately represents the reservoir in both porosity and permeability.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

The present disclosure presents, in accordance with one or more embodiments, methods and non-transitory computer readable mediums for correcting a model having a plurality of cells and representing a reservoir. The method includes obtaining a log of the reservoir, determining, by a computer processor, a log porosity-thickness for each segment of the log of the reservoir, determining a test permeability-thickness relating to each segment of the log of the reservoir using a dynamic pressure transient analysis, determining a relationship between the test permeability-thickness and the log porosity-thickness, determining a model flow capacity and a model storage capacity for the model, determining a calculated flow capacity using the model storage capacity and the relationship, determining a ratio of the calculated flow capacity to the model flow capacity, correcting the model by applying the ratio to each cell, and planning and executing a reservoir production plan based on the model.

The non-transitory computer readable medium stores instructions having functionality for obtaining a log of the reservoir, determining, by a computer processor, a log porosity-thickness for each segment of the log of the reservoir, determining a test permeability-thickness relating to each segment of the log of the reservoir using a dynamic pressure transient analysis, determining a relationship between the test permeability-thickness and the log porosity-thickness, determining a model flow capacity and a model storage capacity for the model, determining a calculated flow capacity using the model storage capacity and the relationship, determining a ratio of the calculated flow capacity to the model flow capacity, correcting the model by applying the ratio to each cell, and planning and executing a reservoir production plan based on the model.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and have been solely selected for ease of recognition in the drawing.

FIG. 1 shows a reservoir in accordance with one or more embodiments.

FIG. 2 shows a porosity log in accordance with one or more embodiments.

FIG. 3 shows a flowchart in accordance with one or more embodiments.

FIG. 4 shows a plot of test permeability-thickness vs. log porosity-thickness in accordance with one or more embodiments.

FIG. 5 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

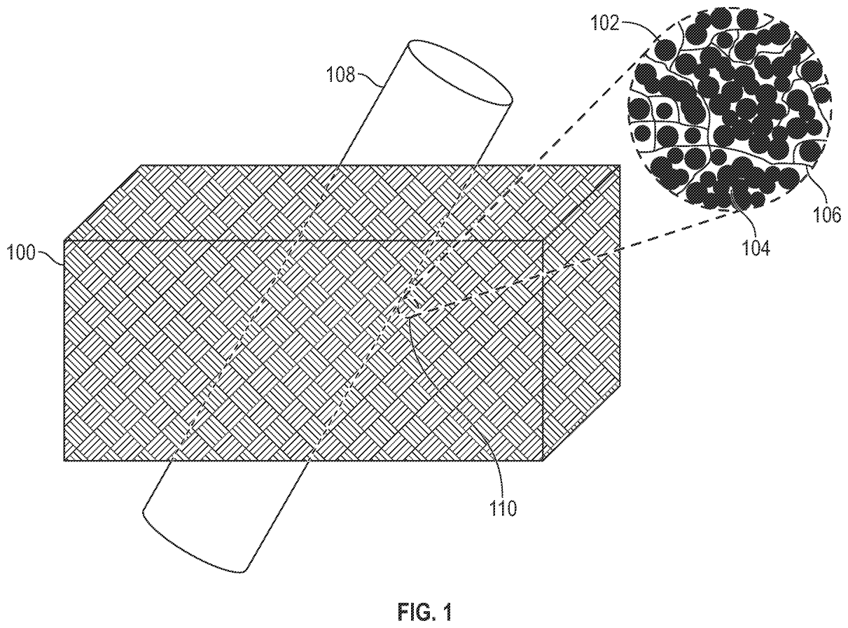

FIG. 1 shows a reservoir (100) in accordance with one or more embodiments. A reservoir (100) is a structure of rock. The reservoir (100) is located beneath the Earth's surface. A sample (110) of the reservoir (100), such as a core sample, may be brought to the surface of the Earth to be studied. The reservoir (100) may consist of a single rock type, such as a sandstone or a carbonate, or may consist of a sequence of rock type over-laying one another. Typically, a reservoir consists of one or more sedimentary rocks. The reservoir (100) may be delineated by a source rock and a cap rock.

The reservoir (100) is made of a plurality of rock grains (102). The spaces between the rock grains (102) are called the pores (104). The pores (104) may or may not contain a fluid, such as a hydrocarbon. The hydrocarbons may be in a gas phase, a liquid phase, or a mixture of the two phases. Further, the pores (104) may contain more than one type of fluid such as a mixture of hydrocarbons and water. Porosity is the ratio of pore (104) volume to total volume of the sample (110) as depicted in Equation (1) where ϕ=porosity; vₚ=volume of the pores (104) in the sample (110); and vₜ=total volume of the sample (110). Porosity is measured as a fraction or a percentage.

$$ϕ = \frac{{v}_{p}}{{v}_{t}} \qquad Equation ( 1 )$$

Permeability is the measurement of the reservoir's (100) ability to transmit fluids. In other words, porosity is the measurement of the interconnected pores (104) of the reservoir (100). Permeability is measured in darcies or millidarcies. Permeability is represented in FIG. 1 by line (106) running through all of the interconnected pores (104). Permeability is more difficult to measure and can be represented by many equations depending on various parameters such as fluid type, fluid phase, etc. The overall reservoir (100) may have an overall porosity and overall permeability; however, the reservoir (100) may be divided into a plurality of sections that each have their own porosity and permeability.

A wellbore (108) is shown running through the reservoir (100). A wellbore (108) is a hole that has been drilled from the surface of the Earth. A wellbore (108) is often drilled into a reservoir (100) to gather data and determine if the reservoir (100) could be a hydrocarbon reservoir. More than one wellbores (108) may be drilled into the reservoir (100) at various locations to analyze the reservoir (100) at said locations. In further embodiments, a wellbore (108) is drilled into the reservoir (100) to produce hydrocarbons or water. Data used from seismic tools, reservoir logging tools, and rock samples taken from the wellbore (108) may be used to create a reservoir simulation model of the reservoir (100).

In one or more embodiments, the model may describe the geometry of the reservoir, such as the location of its upper and lower bounding surfaces and it lateral extent and may describe the spatial variation of the porosity and permeability of the reservoir (100). To be as accurate as possible, the model may be made of a plurality of cells each having their own porosity and permeability. Permeability is one of the most difficult to measure and hence least well constrained parameters when creating the reservoir simulation model. As such, permeability simulated by the model is often corrected based on permeability measurements obtained using a core sample taken from the wellbore (108).

However, core samples are limited in number due to the time and cost of acquiring samples while drilling and coring a wellbore (108). As such, models that correct permeability based on a core sample are frequently inaccurate. Therefore, methods and systems that allow a model to be corrected based on more accessible and accurate data is beneficial. As such, embodiments herein present systems and methods for correcting the model based on a relationship between the dynamic flow capacity of a wellbore (108) obtained from pressure transient analysis and the storage capacity of the reservoir (100) obtained from log measurements.

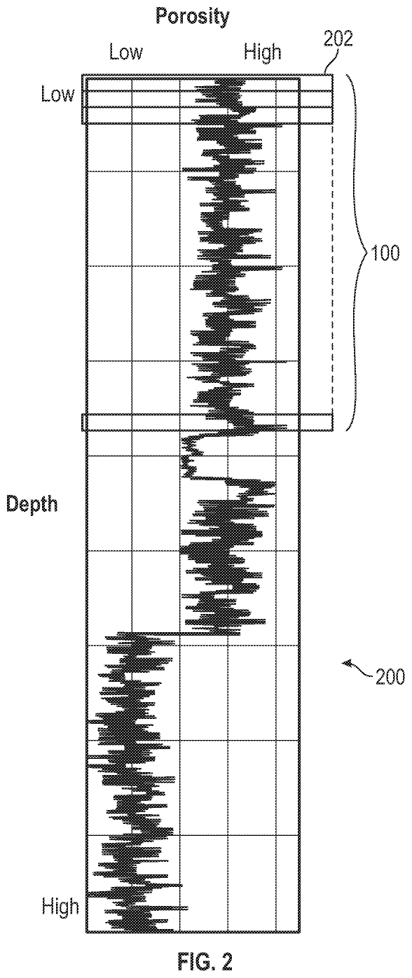

FIG. 2 shows a section of a porosity log (200) in accordance with one or more embodiments. The log (200) is created by inserting a logging tool into a wellbore (108), such as the wellbore (108) depicted in FIG. 1, that intersects the reservoir (100). The logging tool measures various properties at regularly spaced depth intervals along the wellbore (108) as the logging tool is lowered into the wellbore (108). The closely spaced depth intervals may be intervals of 6 inches (15 cm). The logging tool may be made of multiple different tools that can measure different properties of the reservoir (100). For example, the logging tool may have a density tool and a neutron tool which may both be used to determine the porosity.

Specifically, the log (200) depicted in FIG. 2 shows the porosity of a reservoir (100) at all of the depths that make up the reservoir (100). The porosity is indicated along the horizontal axis of the log (200), and the porosity increases along the horizontal axis from left to right. The depth is indicated along the vertical axis of the log (200), and the depth increases top to bottom meaning that the porosity measurements closer to the top of the log (200) are porosity measurements of the portion of the reservoir (100) closer to the surface of the Earth.

Often, the exact depth of the reservoir (100) is unknown, and the log (200) is used to determine the depth of the top and bottom of the reservoir (100). Among other things, the reservoir (100) may be distinguished in the log (200) by noting where there is a section of high porosity. In FIG. 2, the section of the log (200) representing the reservoir (100) is shown using a bracket. This section may be used to estimate the depth of the top and bottom of the reservoir (100) which may be used to estimate the overall thickness of the reservoir (100).

As can be seen by the log (200) depicted in FIG. 2, the measured porosity fluctuates as the logging tool moves down the wellbore (108). In the reservoir simulation model, the section of the log (200) representing the reservoir (100) may be divided into a plurality of small segments (202) such that the porosity of the reservoir (100) may be accurately simulated. In one or more embodiments, the length of each segment (202) is five feet, and the porosity is measured every five feet of the reservoir (100).

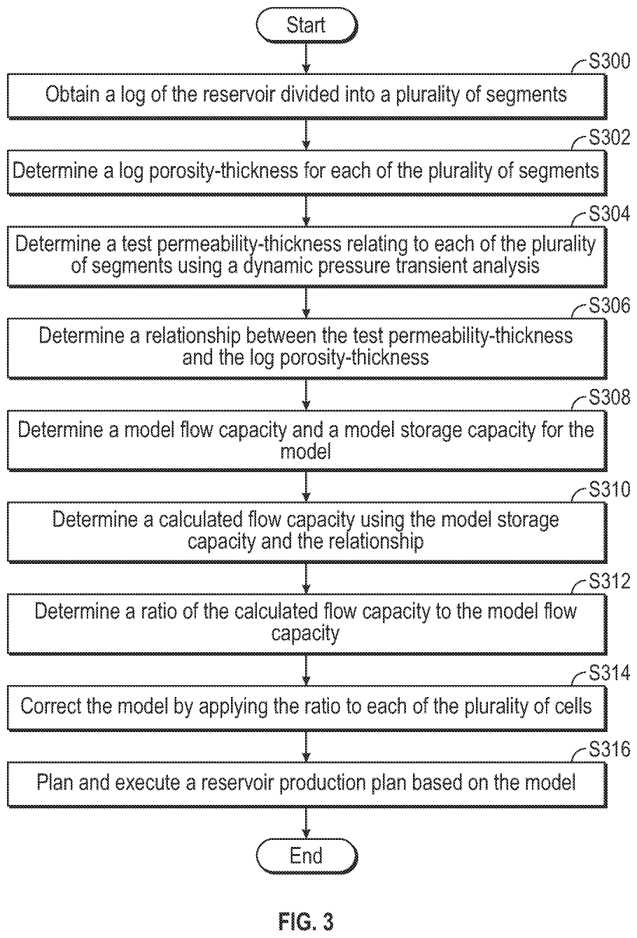

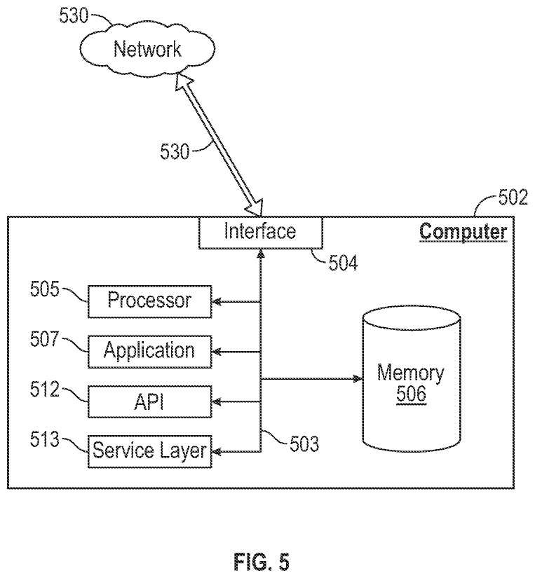

FIG. 3 shows a flowchart in accordance with one or more embodiments. The flowchart outlines a method for correcting a model. The model has a plurality of cells and represents a reservoir. The reservoir may be the reservoir (100) as depicted in FIG. 1. While the various blocks in FIG. 5 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

Initially, a log (200) of the reservoir (100), divided into a plurality of segments (202), is obtained (S300). The log (200) of the reservoir (100) may be similar to the log (200) depicted in FIG. 2. The log (200) may be obtained by running a logging tool on wireline into the wellbore (108). Alternatively, the logging tool may be conveyed on coiled tubing or on drill pipe, either while drilling the wellbore (108) or after the wellbore (108) has been drilled. A log (200) porosity-thickness for each segment (202) of the log (200) of the reservoir (100) is determined using a computer processor (S302). The thickness is the change in depth of the segment (202) from the segment (202) start depth to the segment (202) end depth. For example, the thickness of each segment may equal five feet. The log (200) porosity-thickness is a product of the porosity and the thickness of a singular segment (202) of the log (200).

A test permeability-thickness relating to each segment (202) of the log (200) of the reservoir is determined using a dynamic pressure transient analysis and the computer processor (S304). A dynamic pressure transient analysis is run on the wellbore (108) to measure the flow rate of the reservoir (100) which is equal to the test permeability-thickness. Each segment (202) start depth and end depth (i.e., depth interval) that were used to determine the log porosity-thickness may be the same start depth and end depth of each test permeability-thickness.

More specifically, the test permeability-thickness, or, in other words, the dynamic pressure transient analysis permeability-thickness is obtained by perforating the well across the reservoir (100) and flowing the well. A pressure gauge, located downhole, is used to record the pressure during flow and when the well is shut in. This pressure data is analyzed to obtain the test permeability-thickness.

In further embodiments, a test flow capacity of the entire reservoir (100) may be determined by summing each test permeability-thickness of each segment (202) of the reservoir (100). A log (200) storage capacity of the entire reservoir (100) may be determined by summing each log (200) porosity-thickness of each segment (202) of the reservoir (100).

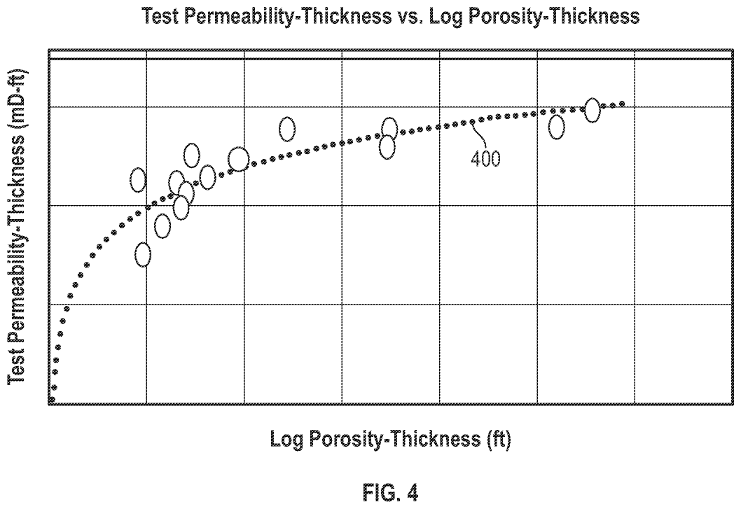

A relationship (400) is determined between the test permeability-thickness and the log (200) porosity thickness using the computer processor (S306). The relationship (400) is determined by plotting the test permeability-thickness versus the log (200) porosity-thickness of each segment (202) of the reservoir (100). FIG. 4 shows an example of a plot of the test permeability-thickness versus the log (200) porosity-thickness. The test permeability-thickness and the log (200) porosity-thickness are matched up by the depth they were taken from to create a data point for each segment (202). Each data point being: (log (200) porosity-thickness, test permeability-thickness). A line is fit through the data points to create a mathematical relationship (400).

A model of the reservoir (100) is created using software stored on the computer processor. The software may be any modeling software known in the art such as Petrel™. The reservoir (100) in the model is created by a plurality of cells. Each cell has a model porosity-thickness and a model permeability-thickness value. A model flow capacity and a model storage capacity for the model is determined using the computer processor (S308). The model flow capacity is the summation of the model permeability-thickness for each cell across the reservoir (100). The model storage capacity is the summation of the model porosity-thickness for each cell across the reservoir (100). Because porosity is a more known variable in the model, the model storage capacity and the log storage capacity should be similar to one another. Because permeability is a more unknown variable in the model, the test flow capacity and the model flow capacity may differ, requiring the model flow capacity to be adjusted.

A calculated flow capacity is determined using the model storage capacity, the relationship (400), and the computer processor (S312). As previously explained, the relationship (400) is represented by a mathematical relationship (400) between the test permeability-thickness and the log (200) porosity-thickness. For example, the mathematical relationship (400) may be Equation (2), below, where y=flow capacity and x=storage capacity.

y=0.17567x_{2.73317} Equation (2)

The model storage capacity value may be inserted into the equation as the x value to determine the calculated flow capacity (the y-value). A ratio of the calculated flow capacity to the model flow capacity is determined using the computer processor (S312). The ratio is determined by dividing the calculated flow capacity, determined from Equation (2), by the model flow capacity, determined by summing the model permeability-thickness of each cell across the reservoir (100). The permeability-thickness values of each cell of the model is corrected by applying the ratio to each cell (S314). This process may be done automatically by the computer processor and the chosen model software.

A reservoir (100) production plan may be planned and executed based on the model (S316) to facilitate the safe and efficient production of hydrocarbons from the reservoir (100). The reservoir (100) production plan may include determining a well path through the reservoir (100) and drilling into the reservoir (100) using a drilling system and utilizing the well path. The plan may further include the type and surface location of the wellbores to be drilled, according to the well path, to reach and penetrate the reservoir (100), and from which to produce hydrocarbons. The plan may include defining the type, size, and location of surface facilities, such as production rigs, pipelines, and GOSPs.

The plan may also include specifying the type of completions to use, including whether wells should be uncased or contain slotted liners, whether hydraulic fracturing, acidizing, or both, is utilized, and whether surface or downhole pumps are needed to produce the hydrocarbons. The plan may further determine whether the injection of fluid, typically water, is required at locations within the reservoir (100) to raise, maintain, or slow the decline in reservoir pressure. Further, the plan may include enhanced recovery methods, such as the injection of steam to reduce the viscosity of oil. The reservoir (100) production plan may be influenced by the assessment of geological, geographical, and economic factors. The geological factors may include the critical desorption pressure and the expected ultimate recovery (EUR) volume of gas from the reservoir (100).

FIG. 5 shows a block diagram of a computer (502) system used to provide computational functionalities associated with described algorithms, methods, functions, processes, flows, and procedures as described in the instant disclosure, according to an implementation. The illustrated computer (502) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (502) may include a computer that includes an input device, such as a keypad, keyboard, touch screen, or other device that can accept user information, and an output device that conveys information associated with the operation of the computer (502), including digital data, visual, or audio information (or a combination of information), or a GUI.

The computer (502) can serve in a role as a client, network component, a server, a database or other persistency, or any other component (or a combination of roles) of a computer system for performing the subject matter described in the instant disclosure. The illustrated computer (502) is communicably coupled with a network (530). In some implementations, one or more components of the computer (502) may be configured to operate within environments, including cloud-computing-based, local, global, or other environment (or a combination of environments).

At a high level, the computer (502) is an electronic computing device operable to receive, transmit, process, store, or manage data and information associated with the described subject matter. According to some implementations, the computer (502) may also include or be communicably coupled with an application server, e-mail server, web server, caching server, streaming data server, business intelligence (BI) server, or other server (or a combination of servers).

The computer (502) can receive requests over network (530) from a client application (for example, executing on another computer (502)) and responding to the received requests by processing the said requests in an appropriate software application. In addition, requests may also be sent to the computer (502) from internal users (for example, from a command console or by other appropriate access method), external or third-parties, other automated applications, as well as any other appropriate entities, individuals, systems, or computers.

Each of the components of the computer (502) can communicate using a system bus (503). In some implementations, any or all of the components of the computer (502), both hardware or software (or a combination of hardware and software), may interface with each other or the interface (504) (or a combination of both) over the system bus (503) using an application programming interface (API) (512) or a service layer (513) (or a combination of the API (512) and service layer (513). The API (512) may include specifications for routines, data structures, and object classes. The API (512) may be either computer-language independent or dependent and refer to a complete interface, a single function, or even a set of APIs. The service layer (513) provides software services to the computer (502) or other components (whether or not illustrated) that are communicably coupled to the computer (502).

The functionality of the computer (502) may be accessible for all service consumers using this service layer. Software services, such as those provided by the service layer (513), provide reusable, defined business functionalities through a defined interface. For example, the interface may be software written in JAVA, C++, or other suitable language providing data in extensible markup language (XML) format or other suitable format. While illustrated as an integrated component of the computer (502), alternative implementations may illustrate the API (512) or the service layer (513) as stand-alone components in relation to other components of the computer (502) or other components (whether or not illustrated) that are communicably coupled to the computer (502). Moreover, any or all parts of the API (512) or the service layer (513) may be implemented as child or sub-modules of another software module, enterprise application, or hardware module without departing from the scope of this disclosure.

The computer (502) includes an interface (504). Although illustrated as a single interface (504) in FIG. 5, two or more interfaces (504) may be used according to particular needs, desires, or particular implementations of the computer (502). The interface (504) is used by the computer (502) for communicating with other systems in a distributed environment that are connected to the network (530). Generally, the interface (504) includes logic encoded in software or hardware (or a combination of software and hardware) and operable to communicate with the network (530). More specifically, the interface (504) may include software supporting one or more communication protocols associated with communications such that the network (530) or interface's hardware is operable to communicate physical signals within and outside of the illustrated computer (502).

The computer (502) includes at least one computer processor (505). Although illustrated as a single computer processor (505) in FIG. 5, two or more processors may be used according to particular needs, desires, or particular implementations of the computer (502). Generally, the computer processor (505) executes instructions and manipulates data to perform the operations of the computer (502) and any algorithms, methods, functions, processes, flows, and procedures as described in the instant disclosure.

The computer (502) also includes a non-transitory computer (502) readable medium, or a memory (506), that holds data for the computer (502) or other components (or a combination of both) that can be connected to the network (530). For example, memory (506) can be a database storing data consistent with this disclosure. Although illustrated as a single memory (506) in FIG. 5, two or more memories may be used according to particular needs, desires, or particular implementations of the computer (502) and the described functionality. While memory (506) is illustrated as an integral component of the computer (502), in alternative implementations, memory (506) can be external to the computer (502).

The application (507) is an algorithmic software engine providing functionality according to particular needs, desires, or particular implementations of the computer (502), particularly with respect to functionality described in this disclosure. For example, application (507) can serve as one or more components, modules, applications, etc. Further, although illustrated as a single application (507), the application (507) may be implemented as multiple applications (507) on the computer (502). In addition, although illustrated as integral to the computer (502), in alternative implementations, the application (507) can be external to the computer (502).

There may be any number of computers (502) associated with, or external to, a computer system containing computer (502), each computer (502) communicating over network (530). Further, the term “client,” “user,” and other appropriate terminology may be used interchangeably as appropriate without departing from the scope of this disclosure. Moreover, this disclosure contemplates that many users may use one computer (502), or that one user may use multiple computers (502).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. A method for correcting a model, having a plurality of cells, representing a reservoir, the method comprising:
obtaining a log of the reservoir, wherein the log is divided into a plurality of segments;
determining, by a computer processor, a log porosity-thickness for each segment of the log of the reservoir;
determining, by the computer processor, a test permeability-thickness relating to each segment of the log of the reservoir using a dynamic pressure transient analysis;
determining, by the computer processor, a relationship between the test permeability-thickness and the log porosity-thickness;
determining, by the computer processor, a model flow capacity and a model storage capacity for the model;
determining, by the computer processor, a calculated flow capacity using the model storage capacity and the relationship;
determining, by the computer processor, a ratio of the calculated flow capacity to the model flow capacity;
correcting, by the computer processor, the model by applying the ratio to each cell; and
planning and executing a reservoir production plan based on the model.

2. The method of claim 1, wherein planning and executing the reservoir production plan further comprises determining a well path through the reservoir and drilling into the reservoir using a drilling system and utilizing the well path.

3. The method of claim 1, wherein determining, by the computer processor, the model flow capacity and the model storage capacity for the model further comprises determining a model permeability-thickness.

4. The method of claim 3, wherein determining, by the computer processor, the model flow capacity and the model storage capacity for the model further comprises determining a model porosity-thickness for each cell of the model.

5. The method of claim 4, wherein the model flow capacity is a summation of the model permeability-thickness for each cell.

6. The method of claim 5, wherein the model storage capacity is a summation of the model porosity-thickness for each cell.

7. The method of claim 1, further comprising determining, by a computer processor, a test flow capacity by summing the test permeability-thickness.

8. The method of claim 1, further comprising determining, by a computer processor, a log storage capacity by summing the log porosity-thickness.

9. The method of claim 1, wherein determining, by the computer processor, the test permeability-thickness and the log porosity-thickness for each segment of the log of the reservoir further comprises estimating an overall thickness of the reservoir using the log.

10. The method of claim 1, wherein the dynamic pressure transient analysis is performed for each segment of the reservoir.

11. A non-transitory computer readable medium storing instructions for correcting a model, having a plurality of cells, representing a reservoir, the instructions comprising functionality for:
obtaining a log of the reservoir, wherein the log is divided into a plurality of segments;
determining, by a computer processor, a log porosity-thickness for each segment of the log of the reservoir;
determining, by the computer processor, a test permeability-thickness relating to each segment of the log of the reservoir using a dynamic pressure transient analysis;
determining, by the computer processor, a relationship between the test permeability-thickness and the log porosity-thickness;
determining, by the computer processor, a model flow capacity and a model storage capacity for the model;
determining, by the computer processor, a calculated flow capacity using the model storage capacity and the relationship;
determining, by the computer processor, a ratio of the calculated flow capacity to the model flow capacity;
correcting, by the computer processor, the model by applying the ratio to each cell; and
planning and executing a reservoir production plan based on the model.

12. The non-transitory computer readable medium of claim 11, wherein planning and executing the reservoir production plan further comprises determining a well path through the reservoir and drilling into the reservoir using a drilling system and utilizing the well path.

13. The non-transitory computer readable medium of claim 11, wherein determining, by the computer processor, the model flow capacity and the model storage capacity for the model further comprises determining a model permeability-thickness.

14. The non-transitory computer readable medium of claim 13, wherein determining, by the computer processor, the model flow capacity and the model storage capacity for the model further comprises determining a model porosity-thickness for each cell of the model.

15. The non-transitory computer readable medium of claim 14, wherein the model flow capacity is a summation of the model permeability-thickness for each cell.

16. The non-transitory computer readable medium of claim 15, wherein the model storage capacity is a summation of the model porosity-thickness for each cell.

17. The non-transitory computer readable medium of claim 11, further comprising determining, by a computer processor, a test flow capacity by summing the test permeability-thickness.

18. The non-transitory computer readable medium of claim 11, further comprising determining, by a computer processor, a log storage capacity by summing the log porosity-thickness.

19. The non-transitory computer readable medium of claim 11, wherein determining, by the computer processor, the test permeability-thickness and the log porosity-thickness for each segment of the log of the reservoir further comprises estimating an overall thickness of the reservoir using the log.

20. The non-transitory computer readable medium of claim 11, wherein the dynamic pressure transient analysis is performed for each segment of the reservoir.
